(19) United States
(12) Patent Application Publication
(10) Pub. No.: US 2010/0289132 A1
(43) Pub. Date: Nov. 18, 2010

(54) SUBSTRATE HAVING EMBEDDED SINGLE PATTERNED METAL LAYER, AND PACKAGE APPLIED WITH THE SAME, AND METHODS OF MANUFACTURING OF THE SUBSTRATE AND PACKAGE

(76) Inventors: Shih-Fu Huang, Zhudong Township (TW); Yuan-Chang Su, Luzhu Township (TW); Chia-Cheng Chen, Zhongli City (TW); Chia-Ching Chen, Kaohsiung City (TW)

Correspondence Address: COOLEY LLP;ATTN: Patent Group, Suite 1100, 777 - 6th Street, NW, WASHINGTON, DC, 20001, US

(21) Appl. No.: 12/716,873

(22) Filed: Mar. 3, 2010

Related U.S. Application Data
(60) Provisional application No. 61/177,652, filed on May 13, 2009.

(30) Foreign Application Priority Data
Jul. 30, 2009 (TW) 98125707

(51) Int. Cl. H01L 23/48; H05K 1/03; H05K 3/10

(52) U.S. Cl. 257/690; 174/255; 29/846; 257/E23.01

(57) ABSTRACT

A substrate having single patterned metal layer applied in a package is provided. The substrate includes a first patterned dielectric layer, a patterned metal layer and a second patterned dielectric layer, wherein the patterned metal layer is embedded in the first patterned dielectric layer. Also, the top surfaces of the patterned metal layer and the first patterned dielectric layer lie in the same plane. At least part of the patterned metal layer are exposed from the holes formed on the lower surface of the first patterned dielectric layer, so as to form plural first contact pads for electrical connection downwardly. The second patterned dielectric layer, formed above the patterned metal layer and the first patterned dielectric layer, at least exposes part of the patterned metal layer to form plural second contact pads at the top surface of the patterned metal layer for electrical connection upwardly.

This application claims the benefits of U.S. Provisional Application No. 61/177,652, filed May 13, 2009 and Taiwan Application No. 98125707, filed Jul. 30, 2009, the subject matter of which is incorporated herein by reference.

### BACKGROUND OF THE INVENTION

1. Field of the Invention

The invention relates in general to a substrate and a package and methods of manufacturing the same, and more particularly to the substrate having an embedded single patterned metal layer, and a package applying the substrate, and methods of manufacturing the substrate and the package.

2. Description of the Related Art

The integrated circuit (IC) package technology plays an important role in the electronics industry. Electronic packaging is for protecting and supporting circuit configuration, creating a path for heat dissipation and providing modularized standard specification form factors for the parts. Electronic packaging in 1990's mainly employs ball grid array (BGA) packaging which is excellent in heat dissipation, has excellent electrical properties and is capable of increasing leads and effectively reducing the surface area of the package.

As lightweight, thinness, compactness, and high efficiency have become universal requirements of consumer electronic and communication products, the chip requires superior electrical properties, a smaller overall volume, and a larger number of I/O ports. As the number of I/O ports increases, the pitch of the integrated circuit is reduced. Thus, it is very difficult to achieve a high efficiency wiring on a BGA substrate or a lead frame substrate. For example, the density of I/O ports increases dramatically starting with the 0.18 μm IC node or high speed (such as 800 MHz above) IC design. Flip chip technology, having high I/O density and excellent electrical properties, is a solution to the above problem and has become one of the mainstreams in the development of electronic carriers. It is a main goal for the manufacturers to develop a substrate with higher density of I/O ports, smaller trace pitches and excellent electrical properties. Besides, in addition to the request of the flip chip technology, the request of systematic integration of the downstream products is also getting more and more urgent. Thus, the multi-chip module (MCM) process has an increased need of the MCM carrier. The MCM carrier and the flip chip carrier have great market potential.

Along with the maturity in the chip scale packaging (CSP) technology, system in package SiP, the systematic semiconductor integration on a package level, which function-wise and cost-wise, has become a mainstream in packaging technology. As the product size becomes smaller and smaller and the function becomes more and more versatile, the SiP technology is used to satisfy the market demands. SiP technology integrates chips of different functions, passive components and other modules together, so that the electronic products have versatile functions. SiP technology also includes different technologies such as 2-dimensional multi-chip module packages and 3-dimensional stacked packages which stack chips of different functions for saving space. As for what type of packaging is most suitable for an application is determined according to the needs of the application. The SiP technology has a wide range of definition, and employs many types of bonding technologies such as wire bonding, flip chip bonding and hybrid-type bonding.

Take the SiP package for example. The SiP package integrates the dice of different digital or analogue functions and bonds the dice on a chip carrier by way of bump bonding or wire bonding. The carrier having embedded passive components or traces possesses electrical properties and is called the integrated substrate or the functional substrate. FIG. 1A˜FIG. 1F schematically shows a progressive flow of manufacturing of a conventional integrated substrate. First, a copper clad laminate (CCL) having a core 102 sandwiched between the first conductive layer 103 and a second conductive layer 104 is provided, as shown in FIG. 1A. The first conductive layer 103 and the second conductive layer 104 are formed of copper. The copper clad laminate is then drilled to form the through hole 106, as shown in FIG. 1B. Next, copper plating step is performed to plate the copper layer 107 on the surfaces of the first and second conductive layers 103 and 104, and also at the sidewall of the through hole 106′, as shown in FIG. 1C. Afterward, the metal trace formation proceeds. As shown in FIG. 1D, a patterned dry film 108 is formed on each copper layer 107. Next, the copper layer (107+103 and 107+104 respectively) is etched according to the patterned dry film 108 (as a mask), as shown in FIG. 1E. Finally, the patterned dry film 108 is removed, and the metal trace (107+103) is revealed. Also, the subsequent steps could be further conducted to complete the final product. For example, a solder mask layer (SM) is printed followed by exposing and developing procedures to expose partial surface of the metal trace (107+103), and a surface treatment is conducted such as plating Ni/Au on the exposed surface of the metal trace (107+103).

For another type of integrated substrate, the through hole in the substrate could be filled with the conductive material such as copper by plating procedure, and the copper layers on two sides of the core are then patterned to form the metal trace. FIG. 2 schematically shows an alternative structure of conventional integrated substrate. However, plating procedure for filling the through hole requires more complicated technique and longer time to plate. Also, it is difficult to control the thickness of the copper layers 115, 116 and 117 (especially copper layer 117).

Since the substrate depicted in FIG. 1F or FIG. 2 mainly include a core layer (102/112) sandwiched between “two conductive layers”, it is so called a 2-L substrate.

To satisfy the requirements of small-sized electronic products, it is a trend to develop a substrate structure with high density of I/O ports and small trace pitches without sacrificing the electrical properties. However, it is difficult to further reduce the size of the conventional structures (such as substrates of FIG. 1F and FIG. 2) using the known manufacturing methods. Besides the size and electrical properties, manufacturing cost of the substrate is also a considerable factor in the device application, especially for the small device with lower market price. Thus, it is an important goal for the manufacturers to develop a novel substrate with low (thin) profile, and manufactured by a simplified process, suitable for mass production and maintaining high production yield, so as to satisfy the desired requirements of the electronic product with low profile and low cost.

### SUMMARY OF THE INVENTION

The present invention provides structures of the substrate having a single patterned metal layer, and the package with this substrate, and methods of manufacturing the same. The substrate of the disclosure merely includes a patterned metal layer (as conductive traces) and two dielectric layers, which reduces the thickness of the substrate. This extra thin substrate is particularly suitable for the application of small-sized, low profile products. Also, the simplified process for manufacturing the substrate is suitable for mass production, while high production yield is still maintained. Compared to the prior art, the substrate structure of the disclosure satisfies the desired requirements of the electronic product with thin profile and low cost.

According to the first aspect of the invention, a substrate having a single patterned metal layer is provided, including a first patterned dielectric layer having a top surface and a bottom surface, a patterned metal layer embedded in the first patterned dielectric layer, and a second patterned dielectric layer formed above the patterned metal layer and the first patterned dielectric layer. A top surface of the patterned metal layer is coplanar with the top surface of the first patterned dielectric layer, wherein at least part of the patterned metal layer are exposed from a pattern of the first patterned dielectric layer so as to form plural first contact pads for downward electrical connection externally. The second patterned dielectric layer at least exposes parts of the patterned metal layer to form plural second contact pads at the top surface of the patterned metal layer for upward electrical connection externally.

According to the second aspect of the invention, a package with the substrate having a single patterned metal layer is provided, comprising the substrate described in the first aspect, at least a die electrically connected to the second contact pads of the substrate, and a molding compound disposed on the top surface of the first patterned dielectric layer so as to cover the first patterned dielectric layer, the patterned metal layer, the second patterned dielectric layer and the die.

According to the third aspect of the invention, a method of manufacturing a substrate having single patterned metal layer is disclosed. First, a patterned metal layer is formed. A first patterned dielectric is then formed on a bottom surface of the patterned metal layer, and a top surface of the first patterned dielectric layer is coplanar with a top surface of the patterned metal layer. At least parts of the bottom surface of the patterned metal layer are exposed so as to form plural first contact pads for downward electrical connection externally. Afterwards, a second patterned dielectric layer is formed on the top surface of the patterned metal layer, and the second patterned dielectric layer at least exposes parts of the patterned metal layer to form plural second contact pads at the top surface of the patterned metal layer for upward electrical connection externally.

Other objects, features, and advantages of the present invention will become apparent from the following detailed description of the preferred but non-limiting embodiment. The following description is made with reference to the accompanying drawings.

### BRIEF DESCRIPTION OF THE DRAWINGS

FIG. 1A˜FIG. 1F schematically shows a progressive flow of manufacturing of a conventional integrated substrate.

FIG. 2 schematically shows an alternative structure of conventional integrated substrate.

FIG. 3A˜FIG. 3I schematically show a progressive flow of manufacturing a substrate having single patterned metal layer according to the first embodiment of the present invention.

FIG. 4 depicts a package with the substrate of FIG. 3I manufactured according to the first embodiment of the present invention.

FIG. 5A is a cross-sectional view of an alternative substrate manufactured according to the second embodiment of the present invention.

FIG. 5B depicts a package with the substrate of FIG. 5A manufactured according to the second embodiment of the present invention.

### DETAILED DESCRIPTION OF THE INVENTION

In the present embodiment, a substrate having an embedded single patterned metal layer, and a package applying the substrate, and methods of manufacturing the substrate and package are disclosed. The substrate of the disclosure is related to a three-layered structure comprising a first patterned dielectric layer, a second patterned dielectric layer, and a patterned metal layer embedded in the first patterned dielectric layer. A top surface of the patterned metal layer is coplanar with a top surface of the first patterned dielectric layer, and at least part of the patterned metal layer are exposed from the first patterned dielectric layer so as to form plural first contact pads for downward electrical connection externally. The second patterned dielectric layer is formed above the patterned metal layer, and at least exposes part of the patterned metal layer to form plural second contact pads (ex: bonding pads) at the top surface of the patterned metal layer for upward electrical connection externally.

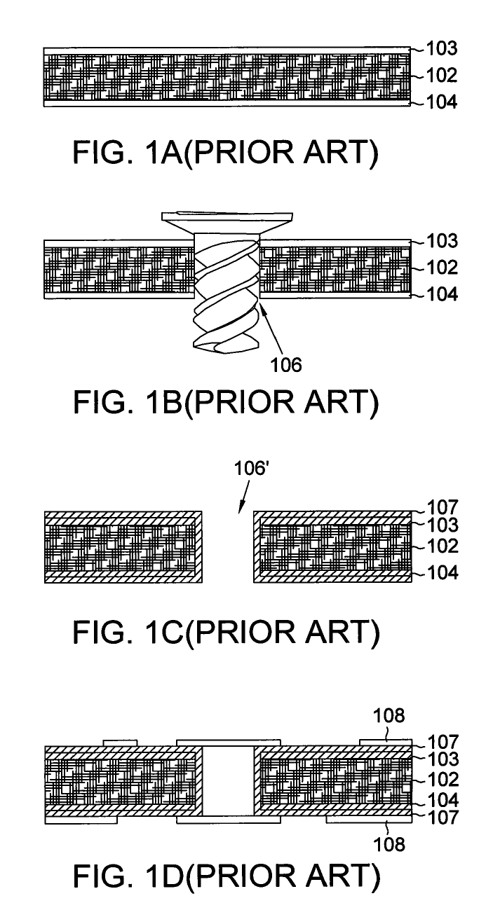

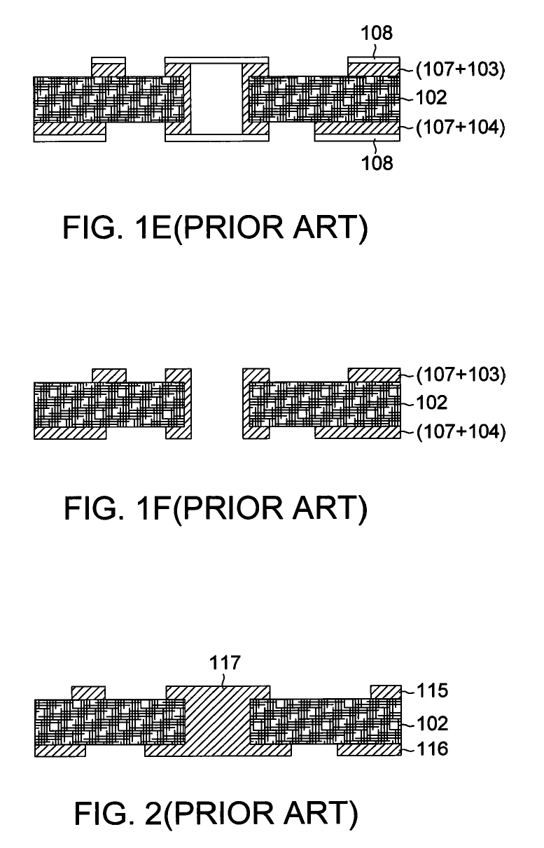

Compared to the prior art as depicted in FIG. 1F and FIG. 2, the thickness of the substrate is significantly reduced giving rise to a lower profile package. This extra thin substrate is particularly suitable for the application of small-sized product. Also, the methods for manufacturing the substrates and packages disclosed herein are simple, easy to perform and suitable for mass production. The substrate manufactured by the method disclosed in the embodiments has advantages of high yield of production, thin profile and low cost, which satisfies the desired requirements of the electronic product in the applications. The electronic product applied with the substrate of the present invention, especially for the small-sized and low-priced product, is very competitive in the commercial market.

Several embodiments are provided to demonstrate the structures of substrate, and the package with the substrate, and methods of manufacturing the substrate and package. The methods of manufacturing the substrates would be slightly modified, without departing from the spirit of the invention, due to the different materials of the patterned base adopted in the embodiments. Also, the configurations of the substrates, material selections and the manufacturing processes described and illustrated in those embodiments are not intended to limit the invention. The modifications and variations can be made without departing from the spirit of the invention to meet the requirements of the practical applications.

Therefore, people skilled in the art would know that the structures and manufacturing methods presented in the embodiments and drawings could be slightly modified under the spirit of the invention. Also, it is also important to point out that the illustrations may not be necessarily be drawn to scale, and that there may be other embodiments of the present invention which are not specifically illustrated. Thus, the specification and the drawings are to be regard as an illustrative sense rather than a restrictive sense. Additionally, the drawings used for illustrating the embodiments and applications of the present invention only show the major characteristic parts in order to avoid obscuring the present invention.

### FIRST EMBODIMENT

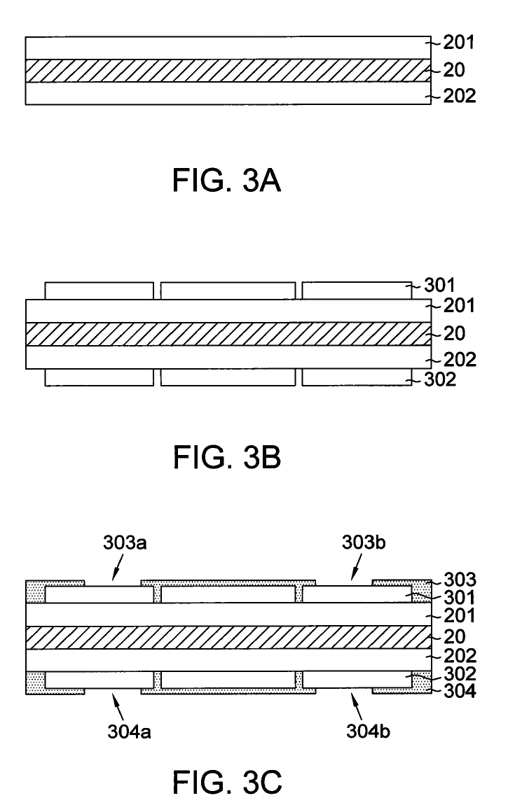

FIG. 3A˜FIG. 3I schematically show a progressive flow of manufacturing a substrate having single patterned metal layer according to the first embodiment of the present invention. First, a structure of an embedded patterned metal layer is formed. In the first embodiment, a carrier is used for an implement to complete the fabrication of the patterned metal layer.

As shown in FIG. 3A, a carrier 20 with the metal foils 201 and 202 on its opposites surfaces is provided. In one embodiment, a copper foil having a thickness of about 12 μm can be used as the metal foil.

As shown in FIG. 3B, the patterned metal layers 301 and 302 are then formed on the metal foils 201 and 202, respectively. Formation of the patterned metal layers 301 and 302 could be done by the following steps. Two metal layers are formed on the metal foils 201 and 202, respectively. Then, a dry film is formed on the metal layer followed by exposing and developing to form a patterned dry film on each sides of the carrier 20. The metal layers are etched according to the patterned dry films to form the patterned metal layers 301 and 302. Finally, the patterned dry films are removed.

Afterwards, the first patterned dielectric layers 303 and 304 are formed on the bottom surfaces of the patterned metal layers 301 and 302, respectively. Also, there are several apertures 303a, 303b formed at the bottom surface of the first patterned dielectric layer 303 to expose parts of the bottom surface of the patterned metal layer 301, as shown in FIG. 3C. Similarly, there are several apertures 304a, 304b formed at the bottom surface of the first patterned dielectric layer 304 to expose parts of the bottom surface of the patterned metal layer 302.

Then, the transitional structures 41 and 42 formed so far are removed from the carrier 20, as shown in FIG. 3D. The transitional structure 41 comprises the metal foil 201, the patterned metal layer 301 and the first patterned dielectric layer 303. Similarly, the transitional structure 42 on the other side of the carrier 20 comprises the metal foil 202, the patterned metal layer 302 and the first patterned dielectric layer 304.

Subsequently, the transitional structures 41 and 42 are removed from the carrier 20 and re-placed inversely on the carrier 20, so that the bottom surfaces of the first patterned dielectric layers 303 and 304 are respectively disposed on the carrier 20, as shown in FIG. 3E.

Then, the metal foils 201 and 202 are removed, as shown in FIG. 3F. It is indicated that the top surface of the patterned metal layer 301 is coplanar with the top surface of the first patterned dielectric layer 303. Similarly, the pattern on the other side of the carrier 20 has indicated that the top surface of the patterned metal layer 302 is coplanar with the top surface of the first patterned dielectric layer 304. Accordingly, the patterned metal layers 301 and 302 are embedded in the first patterned dielectric layers 303 and 304, respectively.

Afterwards, as shown in FIG. 3G, a second patterned dielectric layer 305 is formed on the top surfaces of the patterned metal layer 301 and the first patterned dielectric layer 303. Similarly, the other second patterned dielectric layer 306 is formed on the top surfaces of the patterned metal layer 302 and the first patterned dielectric layer 304. Also, the second patterned dielectric layers 305 and 306 have several through holes 305a, 305b, 306a and 306b to expose parts of the top surfaces of the patterned metal layers 301 and 302, respectively.

Then, the structures formed so far are removed from the carrier 20, as shown in FIG. 3H.

With a suitable carrier 20, this can be done on both sides to allow double sided processing for increased efficiency. Take the substrate formed on the upper side of the carrier 20 (FIG. 3G) for example. At least parts of the bottom surface of the patterned metal layer 301 are exposed by the pattern of the first patterned dielectric layer 303 so as to form several first contact pads 3015 for downward electrical connection externally. In particular applications, the first contact pads 3015 are ball pads, for being filled with a conductive material or attached by the solder balls (not shown) downwardly. The second patterned dielectric layer 305 at least exposes parts of the top surface of the patterned metal layer 301 to function as several second contact pads 3013 for upward electrical connection externally. In typical applications, the second contact pads 2021 are the bonding pads for conductive connection between the substrate and a die/chip of the package. Also, in one embodiment, each of the first patterned dielectric layers 303, 304 and the second patterned dielectric layers 305, 306 may include at least a slot opening so as to expose the first contact pads 3015 and the second contact pads 3013.

In one embodiment, materials of the first patterned dielectric layers 303, 304 and the second patterned dielectric layers 305, 306 may be optionally selected from solder mask (SM), liquid crystal polymer (LCP), prepreg (PP), molding compounds, or other dielectric materials. Also, materials of the first patterned dielectric layers 303, 304 and the second patterned dielectric layers 305, 306 may be the same or different. The materials and selections of the first and second patterned dielectric layers 303-306 are not intended to be limited to these illustrative compounds.

Moreover, the substrate of FIG. 3H may be further optionally subjected to a surface treatment to form the surface finish layers on the exposed surfaces of the patterned metal layer 301, thereby enhancing the electrical connection of the substrate. As shown in FIG. 3I, a first surface finish layer 308a (i.e. positioned between the holes of the second patterned dielectric layer 305) is formed on the surfaces of the second contact pads 3013, and a second surface finish layer 308b (i.e. positioned between the apertures of the first patterned dielectric layer 303) is formed on the surfaces of the first contact pads 3015. Also, materials chosen for making the first surface finish layer 308a and the second surface finish layer 308b could be identical or different. In the present embodiment, materials of the first and second surface finish layers 308a and 308b are independently selected from the group consisting of Ni/Au, NiPdAu, Ni/Ag, Au, Tin, Tin-lead alloy, silver, OSP and combination thereof. Alternatively, the final surface treatments for the first and second contact pads can be done by selective plating of electroless nickel/electroless palladium/immersion gold (ENEPIG) and OSP depending on the requirements of applications. Moreover, in one embodiment, the first surface finish layer 308a formed on the second contact pads 3013 is spaced apart from the sidewalls of the second patterned dielectric layer 305, as illustrated by the distances d1 and d2 of FIG. 3I. These distances d1 and d2 could be identical or different, depending on the requirements of applications.

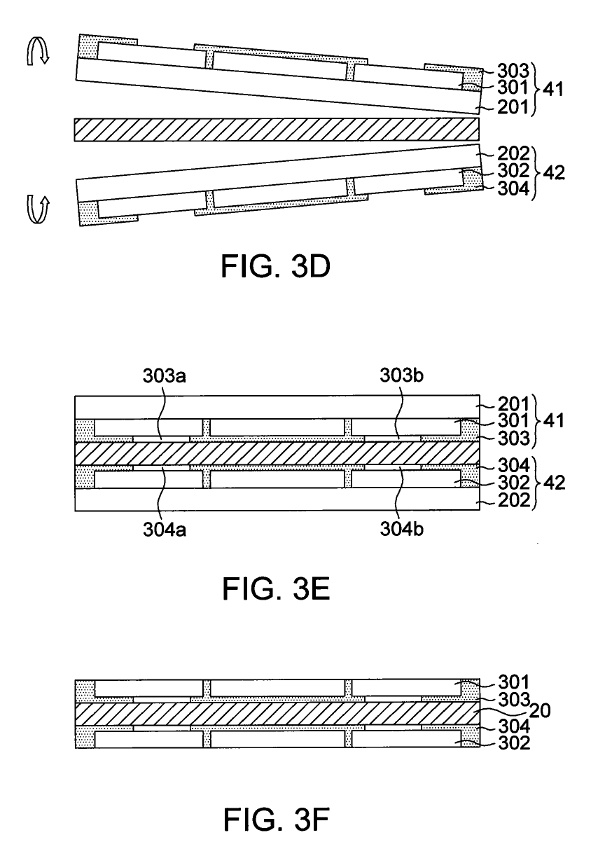

FIG. 4 depicts a package with the substrate of FIG. 3I manufactured according to the first embodiment of the present invention. Package 61 includes the substrate as presented in FIG. 3I, a die 602 disposed on the second patterned dielectric layer 305, the bonding wires 603a, 603b, and a molding compound 607. Lower surface of the die 602 is attached to the second patterned dielectric layer 305 with an adhesive material 601 (such as epoxy). The active surface of the die 602 is electrically connected to the first surface finish layer 308a on the second contact pads 3013 through the bonding wires 603a, 603b. The molding compound 607 is applied onto the first patterned dielectric layer 303 to cover the first patterned dielectric layer 303, the patterned metal layer 301, the second patterned dielectric layer 305, the die 602, and the bonding wires 603a, 603b. The material selected for molding compound 607 should be electrically insulating, such as epoxy.

According to the above descriptions, the patterned metal layer 301 of the substrate, as shown in FIG. 3I and FIG. 4, is embedded in the first patterned dielectric layer 303, and the top surface of the patterned metal layer 301 is aligned with the top surface of the first patterned dielectric layer 303. The second patterned dielectric layer 305 is then formed on the patterned metal layer 301. Compared to the prior art, the substrate structure of the disclosure merely includes two patterned dielectric layers (303/305) and a single patterned metal layer (as conductive traces). The substrate fabricated according to the first embodiment is very thin, having a thickness ranged from about 40 μm to about 130 μm. The package size applied with the substrate of the first embodiment can be effectively kept to a minimum with this combination. This extra thin substrate is particularly suitable for the application of small-sized product. Also, the method disclosed in the first embodiment not only makes the substrate with smaller trace pitch, but also simplifies the substrate manufacturing process.

Although FIG. 3A˜FIG. 3H demonstrate the method of manufacturing the substrates progressing at both sides of the carrier for increasing the production rate, it is not intended to limit the invention to these illustrative sense. The method of manufacturing the substrate can be progressed at single sides of the carrier 20 as required by practical applications.

### SECOND EMBODIMENT

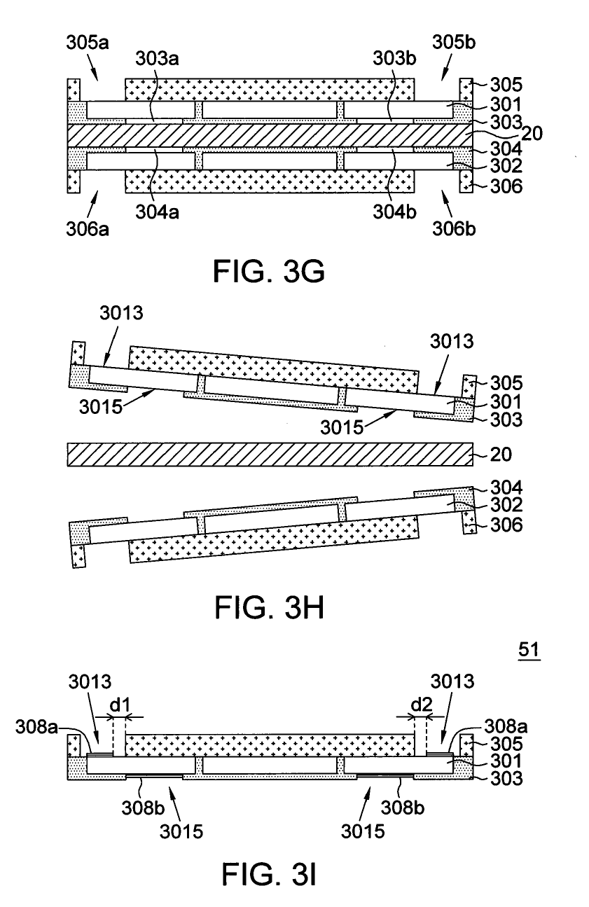

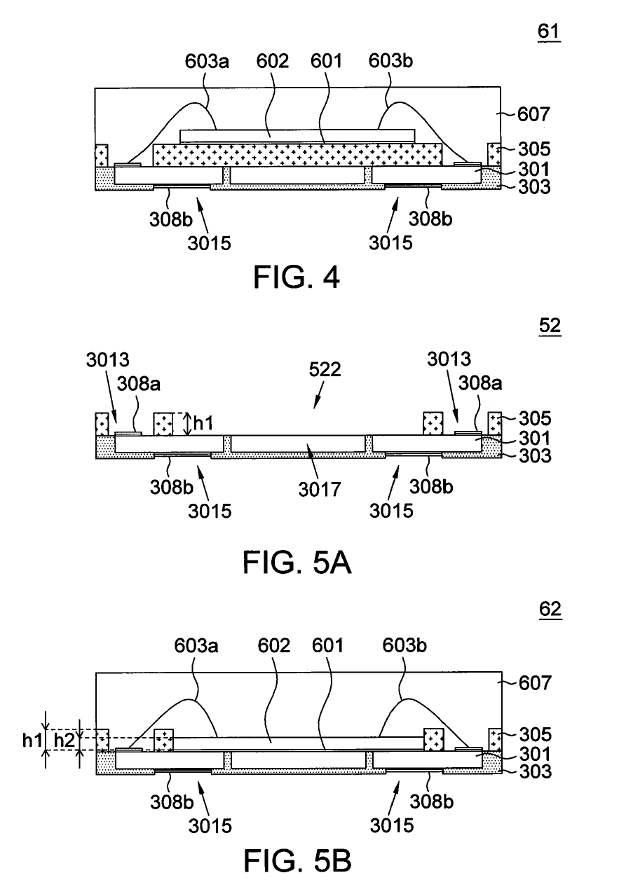

Besides substrate 51 of the first embodiment (FIG. 3I), the substrate structure can be varied by slightly modifying the methods described above without departing from the spirit of the invention. FIG. 5A is a cross-sectional view of an alternative substrate manufactured according to the second embodiment of the present invention. The features of the second embodiment identical to the features of the first embodiment are designated with the same reference numbers.

The method of fabricating the substrate 52 of FIG. 5A could be referred to the process as demonstrated in FIG. 3A˜FIG. 3H. Substrate 52 of FIG. 5A is similar to substrate 51 of FIG. 3I except the die being disposed on the portion of the patterned metal layer 301. In the second embodiment, the patterned metal layer 301 includes a die supporting pad 2071, several first contact pads 3015 (ex: bonding pads) and the second contact pads 3013 (ex: ball pads). Furthermore, the second patterned dielectric layer 305 of the second embodiment has a die-receiving area 522 corresponding to the position of the die supporting pad 3017. As shown in FIG. 5A, the die-receiving area 522 completely exposes the die supporting pad 3017.

FIG. 5B depicts a package with the substrate of FIG. 5A manufactured according to the second embodiment of the present invention. Package 62 includes the substrate as presented in FIG. 5A, a die 602, the bonding wires 603a, 603b, and a molding compound 607. Lower surface of the die 602 is attached to the die supporting pad 3017 of the patterned metal layer 301 within a die-receiving area 522 with an adhesive material 601 (such as epoxy). The active surface of the die 602 is electrically connected to the first surface finish layer 308a on the second contact pads 3013 through the bonding wires 603a, 603b. The molding compound 607 is applied onto the first patterned dielectric layer 303 to cover the first patterned dielectric layer 303, the patterned metal layer 301, the second patterned dielectric layer 305, the die 602, and the bonding wires 603a, 603b. As shown in FIG. 5B, the thickness h2 of the die 602 is smaller than the thickness h1 of the second patterned dielectric layer 305, thereby reducing the overall thickness of the package.

Similarly, the patterned metal layer 301 of the substrate, as shown in FIG. 5A and FIG. 5B, is embedded in the first patterned dielectric layer 303, and the top surface of the patterned metal layer 301 is aligned with the top surface of the first patterned dielectric layer 303. Compared to the prior art, the substrate structure of the disclosure merely includes two patterned dielectric layers (303/305) and a single patterned metal layer (as conductive traces). The substrate fabricated according to the first embodiment is very thin, and the package size applied with the substrate of the embodiment can be effectively kept to a minimum with this combination. This extra thin substrate is particularly suitable for the application of small-sized product.

Although two types of substrates 61, 62, and packages 71 and 72 have been illustrated with reference to specific embodiments, it is noted that the final structure of the substrate can be variable in accordance with requirements of the practical application. For example, the die could be wire bonded or flipped bonded to the substrate. Also, materials and patterns of the metal layer and dielectric layer would be varied from the illustration, depending to the specific requirements of the device. Those skilled in the art will recognize that modifications and variations can be made without departing from the spirit of the invention.

The foregoing description and illustrations contained herein demonstrate many of the advantages associated with the present embodiments over the prior art. By providing substrate having two patterned dielectric layers and a patterned metal layer, the thickness of the substrate is reduced to about 40 μm-130 μm giving rise to a lower profile package. This extra thin substrate is particularly suitable for the application of small-sized product. Also, the methods for manufacturing the substrates and packages disclosed in the foregoing embodiments are simple and suitable for mass production which has advantages of low cost and high yield of production. Compared to the prior art, the substrate structure of the disclosure satisfies the desired requirements of the electronic product with thin profile and low cost. Thus, the electronic product applied with the substrate of the present embodiment, especially for the small-sized and low-priced product, is very competitive in the commercial market.

While the invention has been described by way of example and in terms of the preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A substrate having single patterned metal layer, comprising:
a first patterned dielectric layer, having a top surface and a bottom surface;
a patterned metal layer, embedded in the first patterned dielectric layer, and a top surface of the patterned metal layer coplanar with the top surface of the first patterned dielectric layer, wherein at least part of the patterned metal layer are exposed from the first patterned dielectric layer so as to form plural first contact pads for downward electrical connection externally; and
a second patterned dielectric layer, formed above the patterned metal layer and the first patterned dielectric layer, the second patterned dielectric layer at least exposing part of the patterned metal layer to form plural second contact pads at the top surface of the patterned metal layer for upward electrical connection externally.

2. The substrate according to claim 1, wherein the patterned metal layer comprises at least a die supporting pad.

3. The substrate according to claim 2, wherein at least parts of the die supporting pad is covered by the second patterned dielectric layer.

4. The substrate according to claim 1, further comprising:
a first surface finish layer, formed at least on one or more surfaces of the second contact pads; and
a second surface finish layer, formed at least on one or more surfaces of the first contact pads.

5. The substrate according to claim 4, wherein the first surface finish layer is spaced apart from a sidewall of the second patterned dielectric layer.

6. The substrate according to claim 4, wherein the materials of the first and second surface finish layers are independently selected from the group consisting of Ni/Au, Ni/Ag, Au, Tin, Tin-lead alloy, silver, Ni/Pd/Au, organic solderability preservatives (OSP), and combination thereof.

7. The substrate according to claim 1, wherein each of the first and the second patterned dielectric layers comprises a dielectric material of a solder mask layer (SM), a liquid crystal polymer (LCP), a prepreg (PP), or a molding compound.

8. The substrate according to claim 1, wherein the patterned metal layer further comprises a dummy trace.

9. The substrate according to claim 1, having a thickness ranged from about 40 μm to about 130 μm.

10. A package with substrate having single patterned metal layer, comprising:
a substrate having a single patterned metal layer, comprising a first patterned dielectric layer having a top surface and a bottom surface, a patterned metal layer embedded in the first patterned dielectric layer, and a second patterned dielectric layer formed above the patterned metal layer and the first patterned dielectric layer, wherein a top surface of the patterned metal layer is coplanar with the top surface of the first patterned dielectric layer, at least part of the patterned metal layer are exposed from the first patterned dielectric layer so as to form plural first contact pads for downward electrical connection externally, and the second patterned dielectric layer at least exposing part of the patterned metal layer to form plural second contact pads at the top surface of the patterned metal layer for upward electrical connection externally;
at least a die electrically connected to the second contact pads; and
a molding compound, disposed on the top surface of the first patterned dielectric layer, so as to cover the first patterned dielectric layer, the patterned metal layer, the second patterned dielectric layer and the die.

11. The package according to claim 10, wherein the patterned metal layer comprises at least a die supporting pad.

12. The package according to claim 11, wherein at least parts of the die supporting pad is covered by the second patterned dielectric layer, and the die is disposed on the second patterned dielectric layer.

13. The package according to claim 10, wherein the patterned metal layer further comprises a dummy trace.

14. The package according to claim 10, wherein the substrate has a thickness ranged from about 40 μm to about 130 μm.

15. A method of manufacturing a substrate having single patterned metal layer, comprising:
forming a patterned metal layer;
forming a first patterned dielectric on a bottom surface of the patterned metal layer and a top surface of the first patterned dielectric layer coplanar with a top surface of the patterned metal layer, wherein at least part of the bottom surface of the patterned metal layer are exposed so as to form plural first contact pads for downward electrical connection externally; and
forming a second patterned dielectric layer on the top surface of the patterned metal layer, and the second patterned dielectric layer at least exposing part of the patterned metal layer to form plural second contact pads at the top surface of the patterned metal layer for upward electrical connection externally.

16. The method of manufacturing the substrate according to claim 15, comprising:
providing a carrier with a metal foil formed thereon;
forming the patterned metal layer on the metal foil; and
forming the first patterned dielectric layer on the bottom surface of the patterned metal layer, and the first patterned dielectric layer having a plurality of apertures for exposing at least parts of the bottom surface of the patterned metal layer to form the first contact pads.

17. The method of manufacturing the substrate according to claim 15, comprising:
removing a transitional structure of the metal foil, the patterned metal layer and the first patterned dielectric layer from the carrier;
re-placing the transitional structure by setting the first patterned dielectric layer on the carrier;
removing the metal foil, and the top surface of the patterned metal layer coplanar with the top surface of the first patterned dielectric layer;
forming the second patterned dielectric layer on the top surface of the patterned metal layer;
the second patterned dielectric layer at least exposing parts of the top surface of the patterned metal layer to form the second contact pads; and
removing the carrier.

18. The method of manufacturing the substrate according to claim 17, further being used for forming two sets of the substrate, comprising steps of forming the metal foil at each sides of the carrier; forming the patterned metal layers on both sides of the carrier simultaneously; forming the first patterned dielectric layers; reversing and re-setting the transitional structures on both sides of the carrier; removing the metal foils, forming the second patterned dielectric layers, and removing the carrier.
